(19) United States
(12) Patent Application Publication
(10) Pub. No.: US 2023/0184846 A1
(43) Pub. Date: Jun. 15, 2023

(54) METHOD FOR DIAGNOSING AND PREDICTING THE LIFESPAN OF LEAD-BASED BATTERIES, ESPECIALLY LEAD-BASED BATTERIES INTENDED TO STORE STANDBY POWER

(71) Applicant: COMMISSARIAT À L'ÉNERGIE ATOMIQUE ET AUX ÉNERGIES ALTERNATIVES, Paris (FR)

(72) Inventors: Angel Zhivkov KIRCHEV, Grenoble (FR); Nicolas GUILLET, Grenoble (FR); Lionel SERRA, Grenoble (FR)

(73) Assignee: COMMISSARIAT À L'ÉNERGIE ATOMIQUE ET AUX ÉNERGIES ALTERNATIVES, Paris (FR)

(21) Appl. No.: 18/081,052

(22) Filed: Dec. 14, 2022

(30) Foreign Application Priority Data
Dec. 14, 2021 (FR) 2113461

(51) Int. Cl. G01R 31/392; G01R 31/379; G01R 31/3828; G01R 31/374; G01R 31/389

(52) U.S. Cl. CPC G01R 31/392; G01R 31/374; G01R 31/379; G01R 31/389; G01R 31/3828

(57) ABSTRACT

Method for diagnosing and predicting the lifespan of lead-based batteries, especially lead-based batteries intended to store standby power.

The invention essentially consists in a new method for diagnosing lead-acid batteries and advantageously for estimating their remaining lifespans, the batteries more particularly being intended for standby storage applications.

The method is based on a combination of continuous monitoring measurements with integration of the over-charging current (computation of the over-charging Ah applied to the battery from its installation) and of periodic measurements under DC current of the internal resistance of the battery using short discharging periods with a constant current or a constant power.

### TECHNICAL FIELD

The present invention relates to the field of storage of energy and more particularly that of lead-acid batteries.

It more particularly relates to a method for diagnosing such batteries and advantageously for predicting their lifespan.

Although described with reference to lead-acid batteries, the invention is generally applicable to any electrochemical accumulator employing an aqueous electrolyte, i.e. any “aqueous battery”.

Although described with reference to a preferred standby storage application, the invention is applicable to any stationary application.

### PRIOR ART

A so-called “stationary” battery is a battery that remains where it is placed, in contrast to traction and starter batteries, which are subjected to movements, vibrations, etc. The two main subdivisions of stationary applications are standby power supplies and photovoltaics.

In many applications where interruption of the main electrical power supply, namely the electrical grid, may lead to serious consequences of various types (danger to human health, damage to equipment, financial losses, etc.), systems are backed up by standby power supplies. Mention may be made here of the grids of telecommunication operators, hospitals, power plants, and large data centres (financial centres, centres for controlling air traffic and rail traffic, etc.), etc.

In case of failure of the main grid, the function of the standby power supply is to deliver the power that it was designed to deliver When the standby power supply must replace the electrical grid, and deliver an AC voltage of the same RMS value, this is commonly referred to by the acronym “U.P.S” for Uninterruptible Power Supply.

A standby power supply is dimensioned to compensate for disruptions to the electrical grid to be backed up. These disruptions may be of various natures: blackouts, brownouts and voltage dips, micro-outages, over voltages, etc. A standby power supply may thus be required to deliver power for a few tens of milliseconds to a few minutes.

Rechargeable batteries are used as standby power supplies.

Lead-based batteries are the preferred technology in many standby applications because of their low cost and technological maturity. The requirement of low-cost is related to the fact that the battery is rarely used (i.e. discharged) and thus remains in standby mode over 99% of its lifespan. The maturity of the technology of lead-based batteries is another key advantage, because such applications require very predictable energy storage systems that will never suddenly break down during operation.

A lead-based battery is a set of lead-sulfuric acid accumulators that are connected in series, in order to obtain the desired voltage, and submerged in a liquid electrolyte consisting of demineralized water and sulfuric acid, the accumulators and electrolyte being housed in the same casing.

In order to intervene immediately in case of failure of the grid, standby batteries need to be constantly maintained in the charged state. The conventional mode of maintenance in the charged state is called “float charging”: self-discharging effects are compensated for by applying to the battery a voltage higher than its open-circuit voltage (of the order of 100 to 150 mV per element).

This voltage generates a float-charging current or in other words a charge-maintaining current. This current is permanent: for a battery, for example of 100 Ah capacity, at 20° C., the amplitude of the current of the float charging may stabilize at a value of about 30 mA.

More precisely, float charging is continuously applied voltage-controlled over-charging intended to compensate for the processes of self-discharging, which processes may be expressed by the following equations:

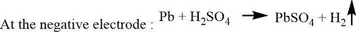

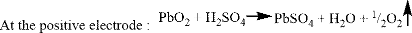

The excess charge, remaining after compensation for the self-discharging processes, drives parasitic electrochemical reactions, namely release of oxygen and corrosion of the current collector at the positive electrode and recombinatorial release of hydrogen and of oxygen (in the case of primary batteries) at the negative electrode. These parasitic reactions may be expressed by the following equations:

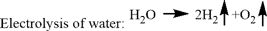

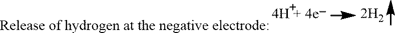

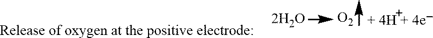

Corrosion of the electrode grid (positive current collector):

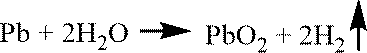

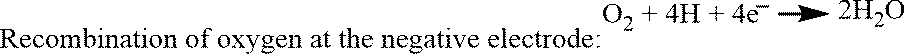

In combination, reactions (4b) and (6) form what is called the oxygen cycle, which allows the lead-acid batteries designated valve-regulated lead-acid (VRLA) batteries to operate without maintenance. This type of battery is equipped with a valve-based safety evacuation system designed to release excessive internal pressure while maintaining a sufficient pressure to allow oxygen and hydrogen to recombine into water.

In contrast, reactions (4a) and (5) may be considered to be irreversible processes that cause gradual degradation of a lead-acid battery.

Degradation occurs via two parallel processes:
on the one hand, the reactions consume water, causing the electrolyte to dry out,
on the other hand, the metal current collector is converted into PbO₂, which is more resistive and brittle, i.e. the positive electrode loses its capacity because of a loss of structural integrity due to the corrosion process.

Progression of these two processes leads to an increase in the resistance of the battery and to a loss of energy-storage capacity.

Standby energy-storage applications require two types of diagnostic parameters to be known for the batteries used within the standby system: the actual capacity of each battery, i.e. its state of health (SOH), and the remaining lifespan of the battery, in order to ensure adequate preventive maintenance of the system.

At the present time, quantitative estimation of the degradation of a standby battery may be carried out using two main methods.

The first main method, which is the most accurate, consists in completely discharging the battery with a constant current or a constant power. By convention, the battery is considered to be completely charged before this discharge test because of the specifications of a standby energy-storage system. The results of this test may be presented directly in terms of “state of health” by normalizing the discharge capacity (Cd) with a reference capacity value (Cref). The state of health (SOH) is thus expressed by the following relationship:

$$\text{SOH = 100 x Cd / Cref}$$

Despite its accuracy, this method is only able to provide information on the actual state of the battery, i.e it does not allow the remaining lifespan of the battery to be predicted. Implementation of this method outside of a laboratory equipped to this end is also problematic because it requires long periods of measurement and of recharging.

The other main method consists in estimating the internal resistance of the battery, or its electrical conductance if its inverse value is taken into account, either through impedance measurements, or through application of DC discharging pulses and correlation thereof with the capacity of the battery or its SOH estimated via the aforementioned complete-discharge method. This approach is widely used in the battery industry, and in particular by the company Midtronics Inc., which is one of the main manufacturers of rapid battery-testing devices. Reference may also be made to publication [1], which describes this method in detail. Just like the complete-discharge method, this method of estimation of internal resistance does not allow the remaining lifespan of the battery to be predicted.

There is therefore a need to improve methods for diagnosing lead-acid batteries employing liquid electrolytes, advantageously for the purpose of predicting their lifespan, especially for standby energy-storage applications.

The aim of the invention is to at least partly meet this need

### DESCRIPTION OF THE INVENTION

To do so, the invention relates, according to one of its aspects, to a method for diagnosing an accumulator or battery employing an aqueous electrolyte, and especially a lead-acid battery, comprising the following steps:
a/ continuously measuring an over-charging current (I_{ovch}) applied to the battery;
b/ periodically measuring, under DC current, the internal resistance (R₁₂₀ₛ) of the battery;
c/ normalizing a parameter derived from the over-charging current measured in step a/ and the internal resistance measured in step b/;
d/ estimating the deviation of the logarithm of the internal resistance normalized in step c/, considered for the parameter derived from the over-charging current normalized in step c/, with respect to a straight calibration line, obtained from a linear regression of calibration measurements of internal resistance and over-charging current of a reference battery;
e/ comparing the estimated deviation (Δ) to a predetermined threshold value depending on the type of battery:
   if the deviation is positive and higher than this threshold value then the battery needs to be changed because of its premature ageing;
   if the deviation is negative and lower than this threshold value then there is no need to change the battery.

According to one advantageous variant, the parameter derived from the measured over-charging current is the integral (Q_{ovch}) of the float over-charging current when the voltage of the battery is maintained at a float-charging value comprised between 2.25 V and 2.3 V/accumulator.

According to another advantageous variant, the normalization of the internal resistance in step c/ is carried out by dividing the measured internal resistance (R₁₂₀ₛ) by the internal resistance of the new battery measured under AC current at 1 kHz or of a new reference battery of the same type.

According to another advantageous variant, the normalization of the over-charging current in step c/ is carried out by dividing the integral of the measured over-charging current (Q_{ovch}) by the nominal capacity (Cn) of the battery, defining an over-charging index (N_{ovch}).

According to one advantageous embodiment, the method further comprises the following steps:
f/ estimating the ratio
$$\left(\frac{\text{Nmax}}{\text{Novch}}\right)$$
between the over-charging limit (Nₘₐₓ) and the over-charging index (N_{ovch}), g/ comparing the ratio
$$\left(\frac{\text{Nmax}}{\text{Novch}}\right)$$
estimated in step f/ to 1:
if the estimated ratio
$$\left(\frac{\text{Nmax}}{\text{Novch}}\right)$$
is lower than 1, then the battery needs to be changed because its normal ageing has been exceeded.

According to another advantageous embodiment, the method further comprises the following step:
if the ratio
$$\left(\frac{\text{Nmax}}{\text{Novch}}\right)$$
compared in step g/ is higher than 1, and
if the absolute value of the deviation (Δ) estimated in step d/ is lower than the predetermined threshold value, then
h/ determining the remaining lifespan (RBLT) of the battery using the equation:
$$R B L T = \left(\frac{{N}_{m a x}}{{N}_{o v c h}} - 1\right) ∗ B O T$$
in which BOT designates the actual time for which the battery has been in service.

Preferably, the periodic measurement of the internal resistance (R₁₂₀ₛ) of the battery in step b/ is carried out with application of a charging or discharging current over a fixed time interval.

Also preferably, the fixed time interval is between 60 and 180 seconds for a discharging current corresponding to the nominal capacity (Cn).

Another subject of the invention is a system (BMS) for controlling a battery employing an aqueous electrolyte, to implement the method just described, the system comprising measurement sensors and a processor that is configured to deliver, on the basis of the measurements taken by the sensors, to the user, messages advising either of failure of the battery, or of correct operation of the battery, and preferably a message indicating the remaining lifespan (RBLT) of the battery.

Another subject of the invention is use of the diagnosing method or of the system that have just been described in an application in which the battery serves as a standby store of electricity, such as in telecommunication base stations, data centres, nuclear plants, or serves as a base and backup for the low-voltage network of an electric car.

Thus, the invention essentially consists in a new method for diagnosing lead-acid batteries and advantageously for estimating their remaining lifespans, the batteries more particularly being intended for standby storage applications.

The method is based on a combination of continuous monitoring measurements with integration of the over-charging current (computation of the over-charging Ah applied to the battery from its installation) and of periodic measurements under DC current of the internal resistance of the battery using short discharging periods with a constant current or a constant power. It may be a question of a current or of a nominal power of 1 h, for example 1 A/Ah or 1 W/Wh.

The results of these measurements are compared to a set of calibration data obtained after linear regression of laboratory tests on the selected type of lead-based battery.

The comparisons give rise to diagnostic indications that indicate whether the monitored battery is ageing normally or prematurely (and therefore is to be changed).

Also on the basis of these comparisons, it is possible to make a prediction of remaining lifespan in terms of days, months or years of service.

Compared to prior-art methods, a method for diagnosing an accumulator or battery according to the invention has many advantages, among which mention may be made of:
reliable method that may be reproduced as desired on any type of battery technology employing an aqueous electrolyte in situ, i.e. without having to move the batteries from their site of commercial use, based on laboratory-tested reference batteries that are used to establish the calibration data;
method for predicting remaining lifespan

The diagnosing method according to the invention is applicable to standby energy-storage applications implementing batteries employing aqueous electrolytes. These applications include telecommunication base stations, data centres, and nuclear plants. Such applications require a low cost and a high predictability and they do not involve intense charging/discharging cycles. These specifications are successfully met by a plurality of different lead-based battery technologies and certain recent market studies have shown that the situation will remain about the same at least in the medium term. For example, the presentation [2] indicates a horizon of 2030.

Another segment of the energy-storage market to which the diagnosing method according to the invention might be advantageously applied is the electric-vehicle market. Most electric vehicles use 12 V lead-acid batteries as base and backup for the low-voltage network of the car (i.e. it is a typical case of application of standby energy storage). According to presentation [2], lead-acid batteries will remain the preferred option in this field at least in the medium term, up to 2030.

Other advantages and features of the invention will become more clearly apparent on reading the detailed description of examples of implementation of the invention, which description is non-limiting and given by way of illustration, with reference to the following figures.

### BRIEF DESCRIPTION OF THE DRAWINGS

FIGS. 1A and 1B are curves illustrating the variation as a function of time in the capacity and high-frequency impedance of a first group of batteries during ageing thereof while applying float charging at 2.27 V/accumulator at 60° C., as in the prior art.

FIGS. 2A and 2B are curves illustrating the variation as a function of time in the capacity and high-frequency impedance of a second group of batteries during ageing thereof while applying float charging at 2.27 V/accumulator at 60° C., as in the prior art.

FIGS. 3A and 3B are curves illustrating the variation as a function of time in the capacity and high-frequency impedance of batteries during ageing while applying float charging at 2.27 V/accumulator at 50° C., as in the prior art.

FIG. 4A, FIG. 4B, FIG. 4C, FIG. 4D are curves illustrating the variation as a function of time in the inspection discharge voltage of batteries during ageing at 60° C., FIGS. 4B and 4D being timewise magnifications of FIGS. 4A and 4C, respectively.

FIGS. 5A and 5B are curves illustrating the variation as a function of time in the internal resistance (R₁₂₀ₛ) under DC current of the batteries during ageing thereof, according to the invention.

FIGS. 6A and 6B are curves illustrating the variation as a function of time in the over-charging current of certain batteries during accelerated ageing thereof while applying float charging at 2.27 V/accumulator at 60° C., according to the invention.

FIGS. 7A and 7B are curves illustrating the variation as a function of time in the cumulative over-charging of batteries during accelerated ageing thereof while applying float charging at 2.27 V/accumulator at 60° C. and 50° C., according to the invention.

FIGS. 8A, 8B and 8C are curves illustrating the correlation between electrical over-charging (Q_{ovch}) and internal resistance (R₁₂₀ₛ) under DC current of batteries at 60° C. and 50° C., based on measurements according to FIGS. 5A to 7B.

FIG. 9 illustrates the linear correlation between the logarithm of normalized internal resistance under DC current and normalized over-charging for batteries exhibiting correct ageing behaviour.

FIGS. 10A and 10B illustrate deviations between the logarithm of normalized internal resistance under DC current as a function of normalized over-charging for batteries not exhibiting correct ageing behaviour with respect to a straight calibration line obtained from the linear correlation of FIG. 9 for a battery exhibiting correct ageing behaviour.

FIGS. 11A and 11B illustrate, depending on the value of the logarithm of normalized internal resistance under DC current as a function of normalized over-charging for a battery, estimation of the remaining lifespan of the battery in a case of correct ageing and in a case of premature ageing.

FIG. 12 is a flowchart of the algorithm of the method for diagnosing a battery and for estimating the remaining lifespan (RBLT) of the battery according to the invention.

### DETAILED DESCRIPTION

It will be noted that in the following description, the voltage of 2.27 V/accumulator refers to the voltage equal to 2.27 V per accumulator of a battery that comprises in the example three accumulators.

### Battery Technology

The inventors have compared prior-art diagnosing methods and implemented their method for diagnosing and predicting the lifespan of batteries using a battery model already available commercially under the reference “Sprinter XP6V2800” - battery manufactured by the company Exide.

This commercially available battery employs a valve-regulated lead-acid (VRLA) battery technology that delivers a voltage equal to 6 V and the liquid electrolyte of which is absorbed and immobilized in fibreglass mats (AGM technology, AGM standing for “Absorbed Glass Mat”), and that comprises three accumulators and has a nominal capacity of 195 Ah.

Typically these batteries are installed in various data centres as standby energy-storage batteries.

It will be noted here that the tested batteries are designated below and in the figures by the acronym “XP6Vnn”, where nn is the numerical reference designating one of the batteries.

### Experimental Protocol

Three groups of four separate batteries were each subject to accelerated ageing using the float-charging voltage of 2.27 V/accumulator and temperatures raised to two temperature levels. Thus, the group consisting of the batteries XP6V06, XP6V07, XP6V08, XP6V09 was subjected to a temperature of 50° C. The groups consisting of the batteries XP6V01, XP6V03, XP6V04, XP6V05 on the one hand and XP6V11, XP6V12, XP6V13, XP6V14 on the other hand were tested at a temperature of 60° C.

Periodic control tests at 25° C. were carried out after 4 to 5 weeks of accelerated ageing at high temperature.

The inspection protocol began with measurement under AC current of the internal impedance of the battery at 1 kHz open-circuit, followed by complete discharge with a constant current equal to 195 A (current of 1 h or C/1 h) until the voltage of the battery reached the value of 1.6 V/accumulator. This measurement was carried out using the instrument sold under the name HIOKI HiTESTER 3554 by the company HIOKI.

After the discharging process, the battery was recharged in a constant-current or constant-voltage regime starting at 19.5 A with a voltage limit of 2.4 V/accumulator The float-charging voltage passed to 2.27 V/accumulator, 24 h after the start of charging and this float-charging voltage was maintained until the start of the next inspection procedure.

Temperature is increased from 25° C. to 50 or 60° C. in the days following the performance of other battery tests included in the inspection procedure. These other tests, which were non-electrical, were non-invasive and did not impact the electrochemistry of the battery. They therefore did not impact the diagnostic measurements according to the prior art and according to the invention.

### Prior-Art Methods for Diagnosing Batteries

Complete-discharge measurements and measurements of internal impedance under AC current at a high frequency of 1 kHz were carried out on the batteries.

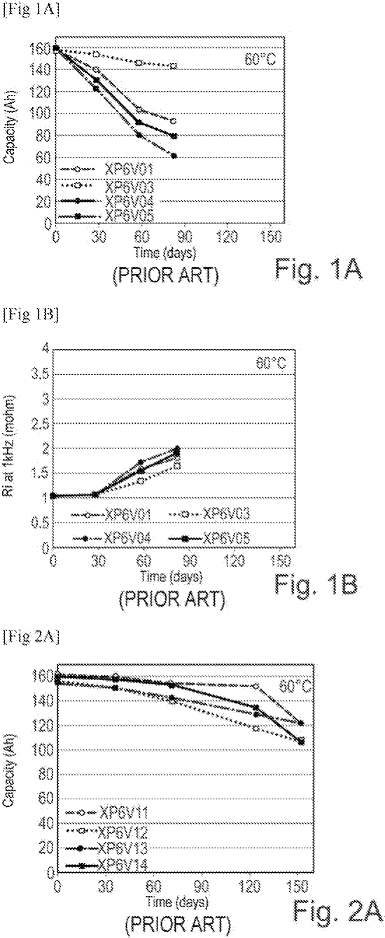

FIGS. 1A, 1B, 2A, 2B and 3A, 3B summarize the results of the battery diagnostics for ageing with application of floating charging at 2.27 V/accumulator to the different groups of batteries at 60° C. and at 50° C., respectively

The first group of batteries tested at 60° C. showed a rapid decrease in the capacity of three batteries, namely XP6V01, XP6V04, XP6V05, this indicating premature failure, and slower ageing of one other battery, namely XP6V03 (FIG. 1A). It is believed that the three batteries of lower quality belonged to a manufacturing batch labelled with a first manufacturing date (May 2019), whereas the battery of correct quality was labelled with a second manufacturing date (November 2018).

The measurements of high-frequency impedance (internal resistance at 1 kHz) showed quite a low correlation with capacity, above all at the start of ageing (FIG. 1B). The internal resistance of the correct battery XP6V03 remained the lowest; however, the difference with respect to the other batteries, namely XP6V01, XP6V04, XP6V05, remained relatively small. These data indicate that high-frequency internal resistance is not a very sensitive parameter in respect of estimation of state of health (SOH) and that it cannot be used for predictive purposes. Specifically, these tests reveal that the variation as a function of time in the 1 kHz impedance remains similar for good batteries and batteries failing prematurely.

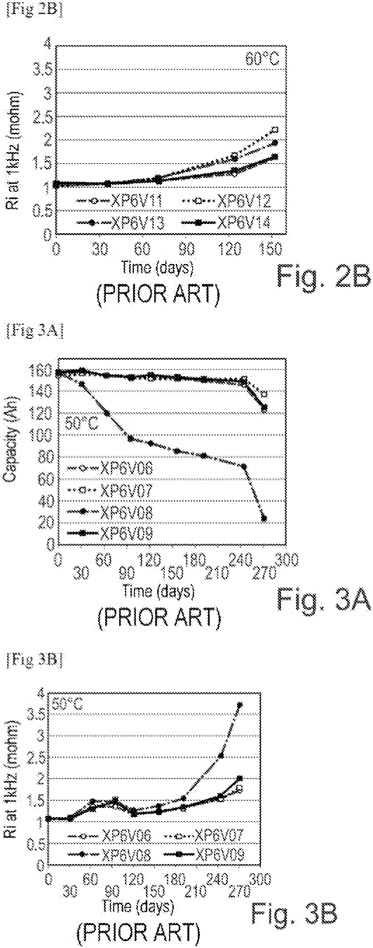

FIG. 2A shows a variation as a function of time in the capacity of the batteries XP6V11, XP6V12, XP6V13, XP6V14, which is quite similar to that of the correct battery XP6V03. These results agree with the information of the data sheet of these batteries, which indicate a battery lifespan of 6 months at 60° C. and under a voltage of 2.27 V/accumulator. The decrease in capacity is not linear and there is a certain dispersion in the data points. FIG. 2B also shows a slow increase in the internal resistance of the batteries XP6V11, XP6V12, XP6V13, XP6V14, which is weakly correlated with the variation as a function of time in capacity These results clearly differ from the data of FIGS. 1A and 1B, where a significant increase in high-frequency impedance is observed after the first month of ageing.

FIG. 3A shows a variation in the capacity and high-frequency impedance of the batteries XP6V06, XP6V07, XP6V08, XP6V09 for ageing with application of float charging at 2.27 V/accumulator at 50° C. It may be seen that the ageing of these batteries is clearly slower than the ageing of the aforementioned batteries. The three batteries XP6V06, XP6V07, XP6V09 that correspond to the manufacturing batch labelled with the second manufacturing date lost their capacity very slowly, whereas the battery XP6V08 drawn from the manufacturing batch labelled with the first manufacturing date rapidly degraded. This confirmed the hypothesis that the premature failure was related to problems with manufacturing quality. The rate of ageing of the correct batteries XP6V06, XP6V07, XP6V09 was in accordance with the information of the data sheet of these batteries, which indicate a battery lifespan equal to 12 months at 50° C. and under a voltage of 2.27 V/accumulator. The variation in the capacity of the correct batteries at 50° C. corresponds very well to the theoretical behaviour of an ageing standby battery: capacity decreases very slowly because of the absence of intense charging/discharging cycling, up to an inflection point. This inflection point corresponds to a certain critical thickness of the corrosion layer formed on the surface of the positive current collectors.

Beyond this thickness, the electrical resistance and the mechanical integrity of the current collector start to degrade far more rapidly, this corresponding to a rapid loss of capacity.

The inflection point in capacity at between 8 and 9 months of ageing in FIG. 3A is indicative thereof.

On reading FIG. 3B, it may also be seen that the variation as a function of time in high-frequency impedance does not correspond well to the variation as a function of time in capacity. It may also be seen that significant differences in capacity may correspond to very small differences in impedance at 1 kHz.

Method for diagnosing batteries via measurements of internal resistance under DC current The internal resistance under current of the battery (RDC) may be estimated using Ohm’s law as follows:

$${\text{R}}_{\text{DC}} = Δ \text{U /} Δ \text{I}$$

where ΔU is the variation in the voltage of the battery due to application of a certain charging or discharging current equal to ΔI over a fixed time interval.

The duration of this time interval is related to the time constants of the various electrical and electrochemical processes occurring in the battery during the charging/discharging operation. For example, a duration lying in the range of 1 to 5 ms will deliver R_{DC} values close to those measured by the Hioki instrument under AC current with a frequency of 1 kHz.

The inventors have analysed in detail the variation as a function of time of the voltage curves of the battery during control discharging at 25° C. with a constant current equal to 195 A (C/1 h), in order to select optimal conditions for the measurement of internal resistance R_{DC} (and more precisely ΔU).

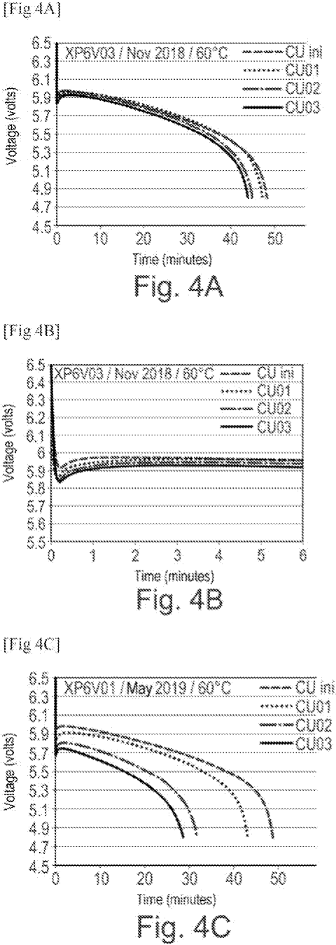

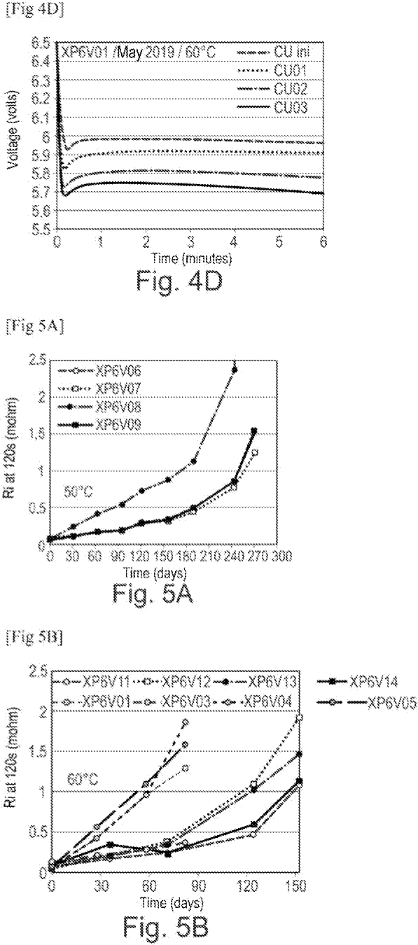

FIGS. 4A to 4D show this variation for the case of two batteries XP6V03 and XP6V01 of the first group having undergone ageing at 60° C. The zoom in on the data of the first 6 minutes of discharging indicates a good correlation between the voltage of the battery, ageing and the variation in capacity, especially in the initial period from 1 to 3 min, corresponding to 1.5 to 5% of the nominal capacity of the battery, where voltage tends to plateau (FIGS. 4B and 4D). This result allows the voltage of the battery measured after 2 min of discharging (denoted U₁₂₀ₛ) with a current equal to 1 C to be considered one of the parameters defining ΔU.

Inspection of all the data measured in the course of the tests, and study of the electrical behaviour of other lead-based batteries during discharging with a current close to 1 C, suggest that a basic reference voltage equal to 2 V/battery, or 6 V/battery for those of the present study, is a suitable empirical choice.

Thus, the inventors have decided to adopt internal resistance under DC current (denoted R120s below) as indicator in the proposed battery-diagnosing method.

This internal resistance will be calculated according to the following equation:

$${\text{R}}_{120 \text{s}} = \left(\text{6 V} - {\text{U}}_{120 \text{s}}\right) \text{/195 A}$$

The variation as a function of time in the internal resistance under DC current (R₁₂₀ₛ) in the course of ageing of the aforementioned three groups of batteries is shown in FIGS. 5A and 5B.

It is clear from these figures that use of this parameter, R₁₂₀ₛ, allows correct batteries and defective batteries to be easily distinguished between, the latter exhibiting a much faster increase in internal resistance.

It may also be seen that decreasing temperature by 10° C. (60° C. in FIG. 5B to 50° C. in FIG. 5A) slows the variation as a function of time in the internal resistances R₁₂₀ₛ by a factor of about 2, this corresponding to the Arrhenius equation.

Comparison of the variation as a function of time in the internal resistances R120s with the variation as a function of time in the capacity of the batteries indicates that values of R120s in the interval from 1 to 2 mohms may ultimately be used as an indicator that the end of a battery’s life is approaching.

Monitoring battery ageing using the integral of over-charging current

It is clear from the data of the preceding figures (FIGS. 1A to 5B) that temperature has a very great impact on the rate of ageing of batteries particularly intended for standby storage applications.

However, the ambient temperature in the spaces where batteries are housed rarely remains constant.

This makes quantification of the ageing of a battery and estimation of its remaining lifespan problematic.

The low number of charging/deep discharging cycles in standby storage applications makes it possible to assume that the active materials of the two electrodes (anode, cathode) of each battery will not degrade as the battery ages.

Thus, the reactions described with reference to equations (3) to (6) may be considered to be the only cause of loss of battery performance.

According to Faraday’s law, which relates the number of species participating in the electrochemical reaction to the number of charge carriers passing through the external electrical circuit, the progress of ageing of a battery is proportional to the over-charging current and to the electrical over-charging, i.e. the amp-hours over-charged.

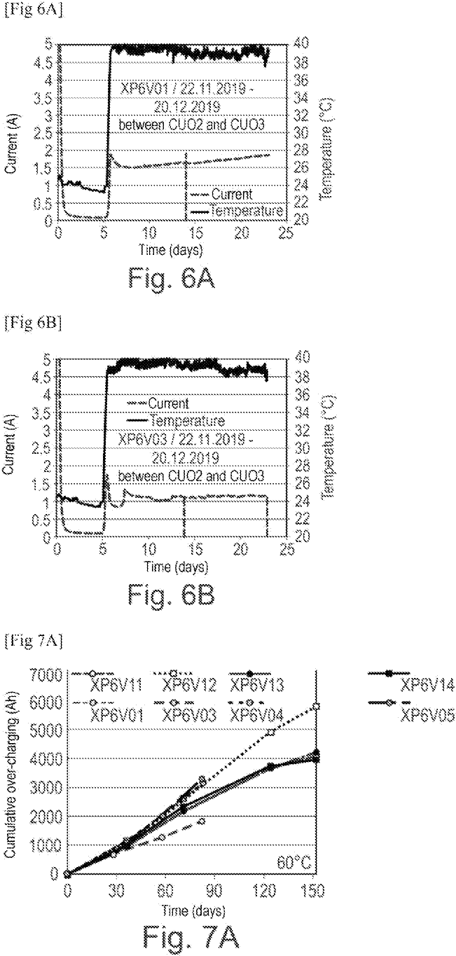

FIGS. 6A and 6B show the variation in over-charging current over the course of accelerated ageing with application of float charging at 2.27 V/accumulator at 60° C. for the case of two batteries XP6V03 and XP6V01 of the first group, respectively. It will be noted here that the acronym CU used in these figures means “check-up”, i.e. a periodic measurement of capacity and internal resistance The numbers 01, 02, 03, etc. following CU for their part are the numbers of each corresponding check-up.

It may be seen that shortly after the increase in temperature, over-charging current also increases and remains in a given range, though it does not remain constant. For this reason, the inventors think that it would be much more practical to use, in float over-charging mode, the integrated current signal as parameter to reveal ageing of the battery.

The integrated current corresponds to computation of the amp-hours over-charged. The amp-hours over-charged may be computed in a number of different ways.

The most accurate approach is subtraction of the amp-hours discharged from the total charge applied to the battery:

$${Q}_{o v c h} = {\int }_{0}^{τ} {I}_{c h} d t - {\int }_{0}^{τ} \left|{I}_{d s c h}\right| d t$$

An approximate method for computing Q_{ovch} is integration of the current applied in float over-charging mode while the voltage of the battery is maintained at 2.27 V/accumulator.

Such an approach may be very effective when the battery is initially recharged in a DC current/DC voltage regime with a voltage of about 2.35 to 2.40 V/accumulator after the end of charging.

In this constant-voltage charging mode, the state of charge of the battery exceeds 99% after a time of 4 to 5 h, whereas over-charging remains negligible.

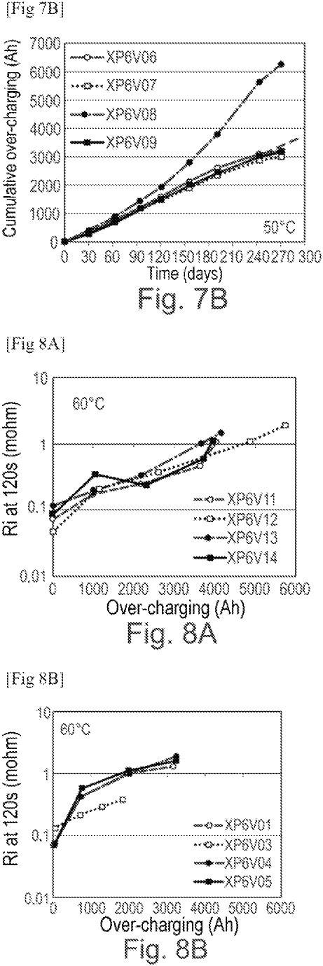

FIGS. 7A and 7B show the variation in the cumulative over-charging (Q_{ovch}) measured in the course of ageing of the aforementioned three groups of batteries, at 60° C. and at 50° C., respectively.

It is clear from these FIGS. 7A and 7B that most of the batteries reach the end of their lives when the total amount of over-charging applied reaches 4000 Ah. This value is practically the same at both ageing temperatures (50° C. and 60° C.). Defective batteries, which age more rapidly, absorb a greater amount of over-charging, i.e they are over-charged with a higher current, this being corroborated by FIGS. 6A and 6B. The variation as a function of time in the cumulative over-charging (Q_{ovch}) is close to a linear progression, especially in batteries having a normal ageing behaviour, i.e. correct batteries.

This result is a convincing indication that cumulative over-charging (Q_{ovch}) is a suitable electrochemical/electrical ageing indicator in the case of standby battery applications using a lead-acid electrochemistry or any other electrochemistry employing an aqueous electrolyte.

Estimation of the lifespan of a battery using the correlation between internal resistance (R₁₂₀ₛ) and cumulative over-charging (Q_{ovch})

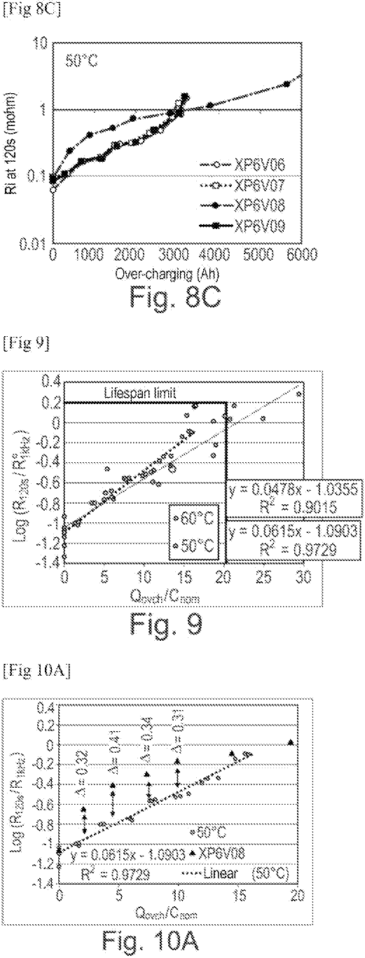

FIGS. 8A, 8B and 8C show the correlation between the battery-diagnostic parameters R₁₂₀ₛ and Q_{ovch} for the aforementioned three groups of batteries, at 60° C. and at 50° C., respectively.

It is clear from FIGS. 8A to 8C that the logarithm of the resistance of correct batteries increases linearly with applied over-charging until the latter reaches a value of 3500 to 4000 Ah. Internal resistance R₁₂₀ₛ begins to increase more rapidly above this value of 3500 to 4000 Ah, this indicating that the end of the battery’s life is rapidly approaching. The linear segments of the curves are similar at both ageing temperatures (50° C. and 60° C.), this showing that this semi-logarithmic relationship between internal resistance (R₁₂₀ₛ) and cumulative over-charging (Q_{ovch}) may be used as calibration data for battery diagnostics and lifespan predictions.

This being so, internal resistance (R₁₂₀ₛ) and applied over-charging (Q_{ovch}) are related to the size of each battery in terms of nominal capacity and of nominal voltage, i.e. the number of accumulators connected in series.

Furthermore, a very wide range of battery models may be manufactured with identical components varying only in their overall dimensions, i.e. with the same thickness of electrode active materials and electrode carriers and separators.

Therefore, it is necessary to normalize the battery parameters R₁₂₀ₛ and Q_{ovch} to make the diagnosing method applicable to an entire range of batteries manufactured using the same type of components, i.e. components of given chemical nature (alloys of the current-collector carriers, electrolyte, compositions of the active electrode materials and separators).

The inventors think that the most practical parameter for normalizing applied over-charging is the nominal capacity (Cn) of the battery. The resultant parameter may be denoted the “over-charging index” or N_{ovch}, defined by the relationship:

$${\text{N}}_{\text{ovch}} = {\text{Q}}_{\text{ovch}} \text{/Cn}$$

The internal resistance R₁₂₀ₛ may for its part advantageously be normalized using the 1 kHz high-frequency internal impedance of a new battery in a completely charged state, or using the value indicated in its data sheet, i.e. the value of a new reference battery of the same type.

The resultant parameter (m) may be written:

$${\text{rn = R}}_{120 \text{s}} {\text{/R}}_{1 \text{kHz}}^{0}$$

FIG. 9 shows calibration data of the method, which was obtained from correct batteries using the normalized parameter rn, as a function of N_{ovch} in a semi-logarithm coordinate system. Optionally, calibration work on batteries of the same type allows a ratio Rn-max beyond which a battery is to be replaced to be determined.

Comparison of the ratio Rn to Rn-max therefore optionally also allows the need to replace a battery to be identified.

The results of the linear fit performed on these calibration data show that the semi-logarithmic relationship between internal resistance R₁₂₀ₛ and applied over-charging N_{ovch} is an empirical modelling approach applicable to battery diagnostics. This linear fit, performed on correctly ageing reference batteries, allows a straight calibration line that is used in the rest of the method to be obtained.

The coefficient of determination (R², i.e. the square of the linear correlation coefficient r) is higher than 0.9 at the two measurement temperatures (50° C. and 60° C.). These coefficients R² are close enough to conclude that the variation in temperature will have no significant impact on predictions of the lifespan of the battery.

Therefore, together the experimental data allow two reliable criteria for predicting end of life to be defined, namely an internal-resistance threshold combined with an over-charging-index threshold.

The data obtained from ageing defective batteries may be used to derive criteria allowing premature-ageing behaviour to be recognized.

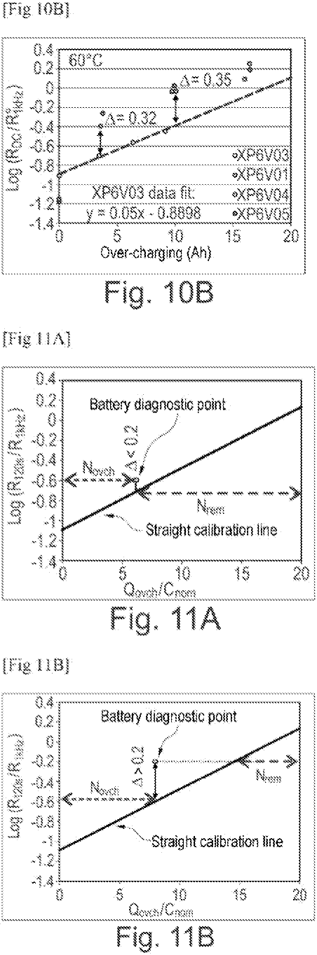

This analysis of data is presented in FIGS. 10A and 10B, at 50° C. and 60° C., respectively. It may be seen that, for a given amount of over-charging, batteries displaying premature-ageing behaviour exhibit a positive deviation Δ from the logarithm of the normalized internal resistance rn. During the first half of the lifespan of the battery, this deviation Δ varies from 0.3 to 0.4

On account of these results and of the dispersion of the data points observed in FIG. 9, a deviation Δ smaller than 0.2 may be considered to be confirmation of normal ageing of the battery whereas a deviation Δ larger than 0.2 will indicate premature ageing.

If the deviation Δ is larger than 0.2 then the remaining lifespan of the battery may be subsequently computed and the user advised should the corresponding battery be in danger of failing imminently.

The results of FIGS. 9, 10A and 10B show that subsequent repetition of the same event, i.e. a deviation Δ > 0.2, may be considered to be a reliable indicator of future battery failure, requiring urgent replacement of the battery.

In contrast, the presence of batteries that have already been recently replaced will show itself through a diagnostic event with a negative deviation, i.e. Δ < -02. In this case, the user may be advised via a message “battery replaced recently”.

The estimation of the remaining lifespan of the battery is shown schematically in FIGS. 11A and 11B for two different diagnostic data points, respectively. In the case of normal ageing of the battery, the diagnostic data point of the battery is close to the calibration line, i.e. the deviation Δ < 0.2.

In this case, the remaining over-charging index (Nᵣₑₘ) may be expressed as follows:

$${\text{N}}_{\text{rem}} = {\text{N}}_{\text{max}} - {\text{N}}_{\text{ovch}}$$

where Nₘₐₓ corresponds to the maximum amount of over-charging tolerable by the battery before it fails and N_{ovch} is the over-charging applied to the battery since the start of commissioning of the use of the standby storage system given that then all the batteries of the system are new. It will be noted here that Nₘₐₓ is equal to 20 for the studied lead-acid technology. This value is derived from the data shown in FIGS. 2A, 3A, 7A and 7B.

Using the nominal capacity (Cn) of the battery, the remaining over-charging index (Nᵣₑₘ) is converted into the remaining number of over-charging amp-hours (Qᵣₑₘ) via the relationship:

$${\text{Q}}_{\text{rem}} = {\text{Cn *N}}_{\text{rem}}$$

Moreover, the number of over-charging amp-hours Qᵣₑₘ is equal to the product of the average over-charging current <I_{ovch>} and of the remaining lifespan of the battery (RBLT) expressed in hours, i.e. to:

$${\text{Q}}_{\text{rem}} = < \text{} {\text{I}}_{\text{ovch}} \text{} > \text{} * \text{RBLT}$$

However, the data of FIGS. 7A and 7B allow the parameter <I_{ovch>} to be considered to be a constant, which may be expressed as the ratio between the applied over-charging, i.e. Q_{ovch} or Cn*N_{ovch}, and the actual time of operation (BOT) of the battery expressed in hours, i.e.:

$$< \text{} {\text{I}}_{\text{ovch}} \text{} > = {\text{Cn*N}}_{\text{ovch}} \text{/ BOT}$$

Combination of equations (13) to (16) allows the following relationship to be obtained for the remaining lifespan of the battery:

$$\text{RBLT} = \left(\frac{{\text{N}}_{\text{max}}}{{\text{N}}_{\text{ovch}}} - 1\right) ∗ \text{BOT}$$

It goes without saying that this equation (17) is not applicable to newly installed batteries because the term Nₘₐₓ/N_{ovch} will be very high. In standby storage applications, this is no problem because storage-system maintenance is generally carried out once per year.

For batteries exhibiting very exaggerated ageing, when N_{ovch} > Nₘₐₓ, then the indicator of RBLT will be negative. In this case the battery management system (BMS) of the battery may advise the user with a message indicating that the battery is to be replaced urgently.

FIGS. 11A and 11B also illustrate the case of premature ageing of the battery, when the normalized internal resistance deviates significantly from the straight calibration line. In this case, the parameter N_{ovch} may be corrected to correspond to the expectancy of a shorter battery lifespan. The experimental data of FIGS. 10A and 10B indicate that two consecutive readings of this type may be cause for generation of a message advising the user to urgently replace this battery.

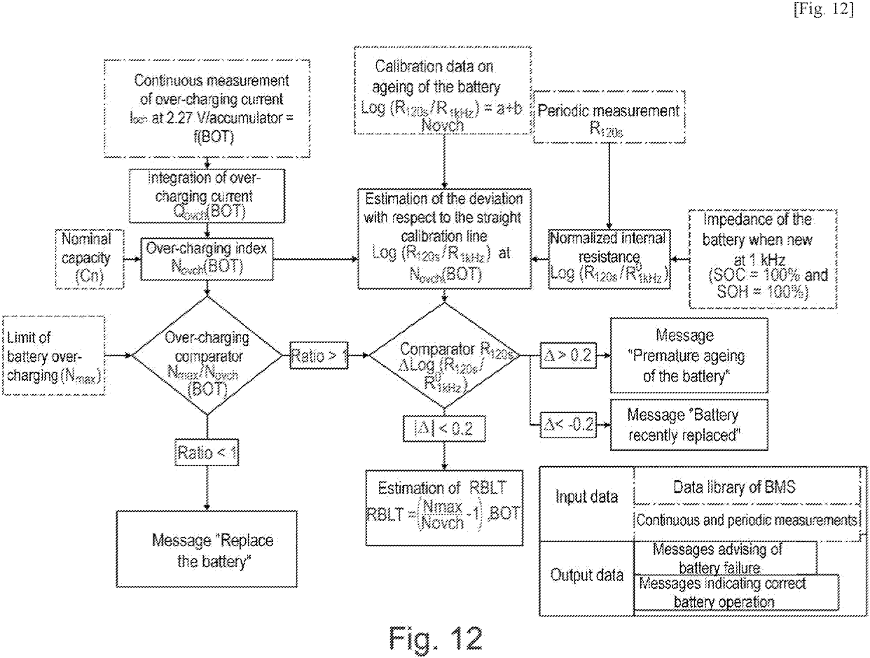

FIG. 12 shows a flowchart of the algorithm of the method according to the invention that has just been described, and which is advantageously implemented by the battery management system (BMS) of the batteries of accumulators. In FIG. 12, data parametrizing the algorithm (BMS data) have been framed with dashed lines, measured battery parameters (monitored parameters) have been framed with dash-dotted lines and output data have been framed therewith and given a grey background. The other internal variables and procedures specific to the method according to the invention have been framed with solid lines.

The invention is not limited to the examples that have just been described; features of the illustrated examples may notably be combined together within variants not illustrated.

Further variants and improvements may be envisaged without departing from the scope of the invention.

In the illustrated example, the results obtained with the battery technology and the experimental protocol employed indicate that the internal-resistance parameter R₁₂₀ₛ is correlated with the electrical resistance of the corrosion layer that develops on the positive current collector. At the start of operation of the battery, the corrosion layer is thin, this leading to a very low value of R₁₂₀ₛ. The data of FIGS. 4A to 4D indicate that the reference value of the voltage of the battery may be set in the interval from 60 to 180 s after the start of discharging. For example, the same type of analysis has been performed with internal-resistance values at 60 s (R₆₀ₛ) and very similar plots to those illustrated in FIGS. 8A to 8C have been obtained.

If the discharging current applied to the battery is modified, it is necessary to correct the duration of the trial discharge and the choice of the battery’s reference voltage.

The correction to the discharging duration is proportional to the applied discharging current. For example, if the discharging current is equal to Cn/0.5h (nominal discharging current for 30 min), the time-range interval will be two times shorter, i.e. from 30 to 90 s (vs 60 to 180 s). In contrast, application of a lower discharging current, for example Cn/2 h will correspond to trial discharging periods two times longer (120 to 360 s).

The correction of the reference voltage at various discharging currents requires an evaluation of the discharging-voltage transient, in order to obtain a normalized internal resistance under DC current that remains in the interval 0.01 to 0.1 mohms, i.e it must be at least one order of magnitude smaller than the internal impedance of the battery measured under AC current at 1 kHz with a state of charge SOC = 100% and a state of health SOH = 100%.

The battery-diagnosing method that has just been described requires separation of the amp-hours corresponding to the process of discharging the electricity used in the main charging reactions. In the illustrated example, with the battery technology and experimental protocol employed, this separation is achieved using data from discharging experiments, i.e. the number of amp-hours discharged is subtracted from the overall charge applied. This is the most accurate approach from the electrochemical point of view. An alternative strategy for estimating over-charging Q_{ovch} is to take into account only the amp-hours injected in float-charging mode, i.e. when the voltage is equal to 2.27 V/accumulator in the case in point. This approach may be very effective if recharging is mainly performed in constant-current/constant-voltage mode with a voltage limit of 2.35 to 2.40 V/accumulator for a relatively short time. For example, constant voltage is applied for a time of 10 to 15 h. Under such conditions, the capacity discharged beforehand is returned to the battery with minimal over-charging, i.e. faradaic efficiency is comprised between 97 and 98%. If recharging is carried out using a limit voltage of 2.27 V/accumulator, the correction of the over-charging may be made by omitting the amp-hours injected into the battery during the first 24 to 48 h in float-charging mode. Such a strategy is reasonable because the corresponding time is much shorter than the typical lifespan of the batteries as specified by their manufacturers. For example, the “Sprinter XP6V2800” technology used is stipulated to have a lifespan of 8 years at 20° C.

### List of Cited References

: D.O. Feder, M.J. Hvalac and S.J. McShane, “Updated status of conductance/capacity correlation studies to determine state-of-health of automotive and stand-by lead/acid batteries”, J Power Sources 48 (1994) 135.

: Presentation by Avicenne Energy “Batteries durables: une nouvelle réglementation cadre et perspectives de marché” organized by EUROBAT, Association of European Automotive and Industrial Battery Manufacturers, webinar on 11 Mar. 2021. https://www.eurobat.org/events/event/48-eurobat-webiinar-sustainable-batteries-a-new-regulatory-framework-and-market-outlook

1. A method for diagnosing an accumulator or battery employing an aqueous electrolyte, and especially a lead-acid battery, comprising the following steps:
a/ continuously measuring an over-charging current (I_{ovch}) applied to the battery;
b/ periodically measuring, under DC current, the internal resistance (R₁₂₀ₛ) of the battery,
c/ normalizing a parameter derived from the over-charging current measured in step a/ and the internal resistance measured in step b/;
d/ estimating the deviation of the logarithm of the internal resistance normalized in step c/, considered for the parameter derived from the over-charging current normalized in step c/, with respect to a straight calibration line, obtained from a linear regression of calibration measurements of internal resistance and over-charging current of a reference battery;
e/ comparing the estimated deviation (Δ) to a predetermined threshold value depending on the type of battery:
if the deviation is positive and higher than this threshold value then the battery needs to be changed because of its premature ageing;
if the deviation is negative and lower than this threshold value then there is no need to change the battery.

2. The diagnosing method according to claim 1, wherein the parameter derived from the measured over-charging current is the integral (Q_{ovch}) of the float over-charging current when the voltage of the battery is maintained at a float-charging value comprised between 2.25 V and 2.3 V/accumulator.

3. The diagnosing method according to claim 1, wherein the normalization of the internal resistance in step c/ is carried out by dividing the measured internal resistance (R₁₂₀ₛ) by the internal resistance of the new battery measured under AC current at 1 kHz or of a new reference battery of the same type.

4. The diagnosing method according to claim 2, wherein the normalization of the over-charging current in step c/ is carried out by dividing the integral of the measured over-charging current (Q_{ovch}) by the nominal capacity (Cn) of the battery, defining an over-charging index (N_{ovch}).

5. The diagnosing method according to claim 4, further comprising the following steps:
f/ estimating the ratio
$$\left(\frac{\text{Nmax}}{\text{Novch}}\right)$$
between the over-charging limit (Nₘₐₓ) and the Novch over-charging index (N_{ovch});
g/ comparing the ratio
$$\left(\frac{\text{Nmax}}{\text{Novch}}\right)$$
estimated in step f/ to 1: Novch
if the estimated ratio
$$\left(\frac{\text{Nmax}}{\text{Novch}}\right)$$
is lower than 1, then the battery needs to Novch
be changed because its normal ageing has been exceeded.

6. The diagnosing method according to claim 5, further comprising the following step:
if the ratio
$$\left(\frac{\text{Nmax}}{\text{Novch}}\right)$$
compared in step g/ is higher than 1, and Novch
if the absolute value of the deviation (Δ) estimated in step d/ is lower than the predetermined threshold value, then
h/ determining the remaining lifespan (RBLT) of the battery using the equation:
$$R B L T = \left(\frac{{N}_{m a x}}{{N}_{o v c h}} - 1\right) ∗ B O T$$
in which BOT designates the actual time for which the battery has been in service.

7. The diagnosing method according to claim 1, wherein the periodic measurement of the internal resistance (R₁₂₀ₛ) of the battery in step b/ is carried out with application of a charging or discharging current over a fixed time interval.

8. The diagnosing method according to claim 7, wherein the fixed time interval is between 60 and 180 seconds for a discharging current corresponding to the nominal capacity (Cn).

9. A system (BMS) for controlling a battery employing an aqueous electrolyte, to implement the method according to claim 1, wherein the system comprises measurement sensors and a processor that is configured to deliver, on the basis of the measurements taken by the sensors, to the user, messages advising either of failure of the battery, or of correct operation of the battery, and preferably a message indicating the remaining lifespan (RBLT) of the battery.

10. The method according to claim 1, wherein the battery serves as a standby store of electricity, or serves as a base and backup for the low-voltage network of an electric car.
